(19) United States
(12) Patent Application Publication
(10) Pub. No.: US 2025/0343064 A1
(43) Pub. Date: Nov. 6, 2025

(54) METHOD OF FABRICATING A SEMICONDUCTOR PACKAGE AND A SEMICONDUCTOR PACKAGE FABRICATED THEREBY

(71) Applicant: Samsung Electronics Co., Ltd., Suwon-si (KR)

(72) Inventors: Chulho JUNG, Suwon-si (KR); Kunsil LEE, Suwon-si (KR)

(73) Assignee: Samsung Electronics Co., Ltd., Suwon-si (KR)

(21) Appl. No.: 18/935,113

(22) Filed: Nov. 1, 2024

(30) Foreign Application Priority Data
May 3, 2024 (KR) 10-2024-0059094

(51) Int. Cl. H01L 21/683; H01L 21/48; H01L 21/56; H01L 23/00; H01L 23/498; H01L 25/03; H01L 25/065; H01L 25/10

(52) U.S. Cl. CPC H01L 21/6836; H01L 21/4857; H01L 21/566; H01L 23/49833; H01L 23/49838; H01L 24/16; H01L 24/32; H01L 24/48; H01L 24/73; H01L 24/96; H01L 24/97; H01L 25/03; H01L 25/0655; H01L 25/105; H01L 2224/16227; H01L 2224/16235; H01L 2224/16238; H01L 2224/32225; H01L 2224/48227; H01L 2224/73204; H01L 2224/73265; H01L 2224/96; H01L 2224/97; H01L 2924/1815

(57) ABSTRACT

A method of fabricating a semiconductor package may include attaching an adhesive layer to a carrier substrate. The adhesive layer may include a first region in contact with the carrier substrate and a second region on the first region. The second region may include metal particles, and a density of the metal particles in the second region may increase as a distance from the first region increases.

### CROSS-REFERENCE TO RELATED APPLICATIONS

This U.S. non-provisional patent application claims priority under 35 U.S.C. § 119 to Korean Patent Application No. 10-2024-0059094, filed on May 3, 2024, in the Korean Intellectual Property Office, the entire contents of which are hereby incorporated by reference.

### BACKGROUND OF THE INVENTION

At least some example embodiments relate to methods of fabricating a semiconductor package and semiconductor packages fabricated thereby, for example to a method of fabricating a semiconductor package using an adhesive layer with a metal particle region and a semiconductor package fabricated thereby.

A semiconductor package is configured to easily use an integrated circuit chip as a part of an electronic product. In general, the semiconductor package includes a printed circuit board (PCB) and a semiconductor chip, which is mounted on the PCB and is electrically connected to the PCB using bonding wires or bumps. With development of the electronic industry, many studies are being conducted to improve reliability and durability of the semiconductor package.

### SUMMARY

At least some example embodiments of inventive concepts provide a method for increasing productivity in a process of fabricating a semiconductor package.

Some example embodiments of inventive concepts provide a semiconductor package with improved durability.

According to some example embodiments of inventive concepts, methods of fabricating a semiconductor package may include attaching an adhesive layer to a carrier substrate. The adhesive layer may include a first region in contact with the carrier substrate and a second region on the first region. The second region may include metal particles, and a density of the metal particles in the second region may increase as a distance from the first region increases.

According to some example embodiments of inventive concepts, a method of fabricating a semiconductor package may include attaching an adhesive layer to a carrier substrate, forming a first redistribution substrate on the adhesive layer, mounting a semiconductor device on the first redistribution substrate, irradiating light through the carrier substrate to cure the adhesive layer, and detaching the carrier substrate and the adhesive layer from the first redistribution substrate. The adhesive layer may include a first region in contact with the carrier substrate and a second region on the first region and is in contact with the first redistribution substrate. The second region may include metal particles, and a diameter of the metal particles may range from 50 nm to 100 μm.

According to some example embodiments of inventive concepts, a method of fabricating a semiconductor package may include attaching an adhesive layer to a carrier substrate, forming a first redistribution substrate on the adhesive layer, mounting a semiconductor device on the first redistribution substrate, forming a second redistribution substrate on the first redistribution substrate and on the semiconductor device, irradiating light through the carrier substrate to cure the adhesive layer, and detaching the carrier substrate and the adhesive layer from the first redistribution substrate. The adhesive layer may include a first region in contact with the carrier substrate and a second region on the first region and in contact with the first redistribution substrate. The second region may include metal particles, and the metal particles may be absent in the first region.

According to some example embodiments of inventive concepts, a semiconductor package may include a first redistribution substrate including a plurality of first redistribution layers that are sequentially stacked, first conductive patterns below the lowermost one of the first redistribution layers, first connection members bonded to the first conductive patterns, respectively, a first semiconductor chip on the first redistribution substrate, a first molding member at least partially covering the first redistribution substrate and the first semiconductor chip, a plurality of conductive pillars at least partially extending through the first molding member and in contact with the first redistribution substrate, and a second redistribution substrate on the first molding member. A bottom surface of the lowermost one of the first redistribution layers may have an uneven structure.

### BRIEF DESCRIPTION OF THE DRAWINGS

FIG. 1 is a sectional view illustrating a semiconductor package according to some example embodiments of inventive concepts.

FIG. 2 is an enlarged sectional view illustrating a portion ‘P1’ FIG. 1.

FIGS. 3A and 3B are sectional views, each illustrating a carrier adhesive member according to some example embodiments of inventive concepts.

FIG. 4 is a flow chart illustrating a method of fabricating a semiconductor package according to some example embodiments of inventive concepts.

FIGS. 5A to 5L are sectional views sequentially illustrating a method of fabricating a semiconductor package, according to some example embodiments of inventive concepts.

FIG. 6 is a sectional view illustrating a semiconductor package according to some example embodiments of inventive concepts.

FIG. 7 is a sectional view illustrating a semiconductor package according to some example embodiments of inventive concepts.

FIG. 8 is a sectional view illustrating a semiconductor package according to some example embodiments of inventive concepts.

FIG. 9 is a sectional view illustrating a semiconductor package according to some example embodiments of inventive concepts.

FIG. 10 is a sectional view illustrating a semiconductor package according to some example embodiments of inventive concepts.

### DETAILED DESCRIPTION

Some example embodiments of the inventive concepts will now be described more fully with reference to the accompanying drawings, in which some example embodiments are shown.

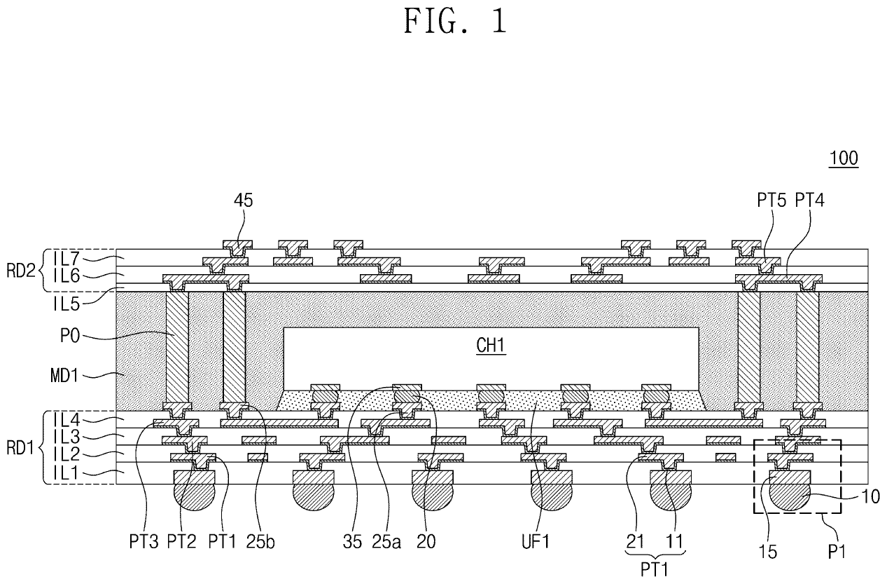

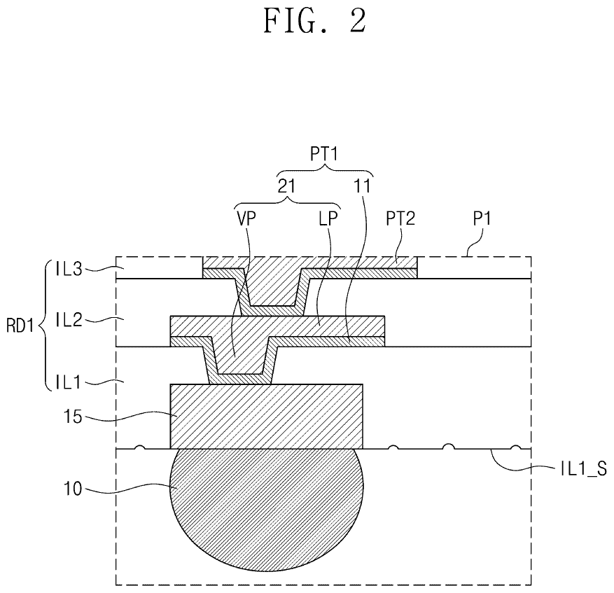

FIG. 1 is a sectional view illustrating a semiconductor package according to some example embodiments of inventive concepts. FIG. 2 is an enlarged sectional view illustrating a portion ‘P1’ FIG. 1.

Referring to FIG. 1, a semiconductor package 100 may have the structure of a chip-last-type fan-out wafer level package (FOWLP). The semiconductor package 100 may include a first redistribution substrate RD1, a second redistribution substrate RD2, a first semiconductor device CH1, conductive pillars P0, and a first molding member MD1.

The first semiconductor device CH1 may be mounted on the first redistribution substrate RD1. The first semiconductor device CH1 may be or include at least one semiconductor chip. For example, the first semiconductor device CH1 may be or include a logic chip. The first redistribution substrate RD1 and the first semiconductor device CH1 may be covered or at least partially covered with the first molding member MD1. The second redistribution substrate RD2 may be disposed on the first molding member MD1. The conductive pillars P0 may be provided to penetrate (for example, extend or at least partially extend through) the first molding member MD1 and to electrically connect the first redistribution substrate RD1 to the second redistribution substrate RD2.

The first redistribution substrate RD1 may include, for example, first to fourth redistribution layers IL1, IL2, IL3, and IL4, which are sequentially stacked. However, inventive concepts are not limited to this example, and the first redistribution substrate RD1 may be composed of three or less redistribution layers or five or more redistribution layers. Each of the first to fourth redistribution layers IL1, IL2, IL3, and IL4 may include, for example, a photoimageable dielectric (PID) layer, but example embodiments are not limited thereto. Alternatively, or additionally, each of the first to fourth redistribution layers IL1, IL2, IL3, and IL4 may include, for example, a curable insulating layer (e.g., an Ajinomoto build-up film (ABF)).

First redistribution patterns PT1 may be disposed between the first redistribution layer IL1 and the second redistribution layer IL2. Second redistribution patterns PT2 may be disposed between the second redistribution layer IL2 and the third redistribution layer IL3. Third redistribution patterns PT3 may be disposed between the third redistribution layer IL3 and the fourth redistribution layer IL4. First and second conductive patterns 25a and 25b may be disposed between the fourth redistribution layer IL4 and the first molding member MD1.

Under-bump patterns 15 may be disposed on a bottom surface of the first redistribution layer IL1. The under-bump patterns 15 may be in contact (for example, direct contact) with the first redistribution patterns PT1, respectively. Each of the first to third redistribution patterns PT1 to PT3, the first and second conductive patterns 25a and 25b, and the under-bump patterns 15 may be formed of or include at least one of copper, aluminum, tungsten, nickel, gold, tin, and titanium. In the present specification, the under-bump patterns 15 may be referred to as “conductive patterns”.

First connection members 10 may be connected (for example, bonded) to the under-bump patterns 15. The first connection members 10 may include at least one of solder balls, conductive bumps, and conductive pillars. The first connection members 10 may be formed of or include at least one of, for example, tin, lead, silver, copper, aluminum, gold, nickel, or any alloys thereof, but example embodiments are not limited thereto.

Third conductive patterns 35 may be disposed on a bottom surface of the first semiconductor device CH1. The first semiconductor device CH1 may be connected to the first redistribution substrate RD1 by, for example, a flip-chip bonding method using second connection members 20. The second connection members 20 may electrically connect the third conductive patterns 35 of the first semiconductor device CH1 to corresponding ones of the first conductive patterns 25a. The second connection members 20 may include at least one of, for example, solder balls, conductive bumps, and conductive pillars. The second connection members 20 may be formed of or include at least one of tin, lead, silver, aluminum, gold, nickel, or any alloys thereof, but example embodiments are not limited thereto.

A first under fill UF1 may be interposed between the first semiconductor device CH1 and the first redistribution substrate RD1. The first under fill UF1 may be formed through, for example, dispensing and curing processes. The first under fill UF1 may include, for example, an epoxy resin and may protect the second connection members 20.

The first molding member MD1 may cover or at least partially cover a top surface of the first redistribution substrate RD1 and the first semiconductor device CH1. The first molding member MD1 may include, for example, an insulating resin (e.g., an epoxy-based molding compound (EMC)). The first molding member MD1 may further include fillers, which are dispersed in the insulating resin, but example embodiments are not limited thereto. In some example embodiments, the filler may be formed of or include silicon oxide (SiO₂).

The second redistribution substrate RD2 may be disposed on the first semiconductor device CH1 and the first molding member MD1. The second redistribution substrate RD2 may include fifth to seventh redistribution layers IL5, IL6, and IL7, which are sequentially stacked. However, inventive concepts are not limited to this example, and the second redistribution substrate RD2 may be composed of four or more redistribution layers. Each of the fifth to seventh redistribution layers IL5, IL6, and IL7 may include, for example, a photoimageable dielectric (PID) layer, but example embodiments are not limited thereto. Alternatively, or additionally, each of the fifth to seventh redistribution layers IL5, IL6, and IL7 may include, for example, a curable insulating layer (e.g., an Ajinomoto build-up film (ABF)).

Fourth redistribution patterns PT4 may be disposed between the fifth redistribution layer IL5 and the sixth redistribution layer IL6. Fifth redistribution patterns PT5 may be disposed between the sixth redistribution layer IL6 and the seventh redistribution layer IL7. Fourth conductive patterns 45 may be disposed on the seventh redistribution layer IL7. Each of the fourth and fifth redistribution patterns PT4 and PT5 and the fourth conductive patterns 45 may be formed of or include, for example, at least one of copper, aluminum, tungsten, nickel, gold, tin, titanium, or any alloys thereof, but example embodiments are not limited thereto.

The conductive pillars P0 may be disposed to be spaced apart from the first semiconductor device CH1. Although not shown, the conductive pillars P0 may be disposed to enclose (for example, surround or at least partially surround) the first semiconductor device CH1, when viewed in a plan view. Any or each of the conductive pillars P0 may be electrically connected to a corresponding one of the second conductive patterns 25b. Any or each of the conductive pillars P0 may be electrically connected to a corresponding one of the fourth redistribution patterns PT4. Top surfaces of the conductive pillars P0 may be coplanar or substantially coplanar with a top surface of the first molding member MD1. The conductive pillars P0 may be formed of or include, for example, at least one of conductive materials (e.g., copper (Cu)).

Referring to FIGS. 1 and 2, each of the first to fifth redistribution patterns PT1 to PT5 may include a barrier/seed layer 11 and a pattern portion 21. The pattern portion 21 may include a via portion VP and a line portion LP, which is placed on the via portion VP and has a line or line-like shape. The via portion VP and the line portion LP may be configured to form a single object. A width of the via portion VP may decrease in a downward direction (for example, when moving downwards in a vertical direction). Alternatively, some of the first to fifth redistribution patterns PT1 to PT5 may be provided to have only the line portion LP and not the via portion LP.

Bottom surfaces of the first to fifth redistribution patterns PT1 to PT5 may be covered or at least partially covered with the barrier/seed layer 11. The barrier/seed layer 11 may include a barrier layer and a seed layer, which may be sequentially stacked. The barrier layer may include, for example, a metal nitride layer, but example embodiments are not limited thereto. The seed layer may include the same metallic material as the first to fifth redistribution patterns PT1 to PT5.

A bottom surface IL1_S of the first redistribution layer IL1 may have, for example, an uneven or substantially uneven structure. Interfaces between the first to fourth redistribution layers IL1 to IL4 may be flat or substantially flat. A surface roughness of a top surface of the fourth redistribution layer IL4 may be smaller (for example, less or substantially less) than a surface roughness of the bottom surface IL1_S of the first redistribution layer IL1. A surface roughness of a bottom surface of one of the first to third redistribution patterns PT1 to PT3 may be smaller (for example, less or substantially less) than a surface roughness of the bottom surface IL1_S of the first redistribution layer IL1.

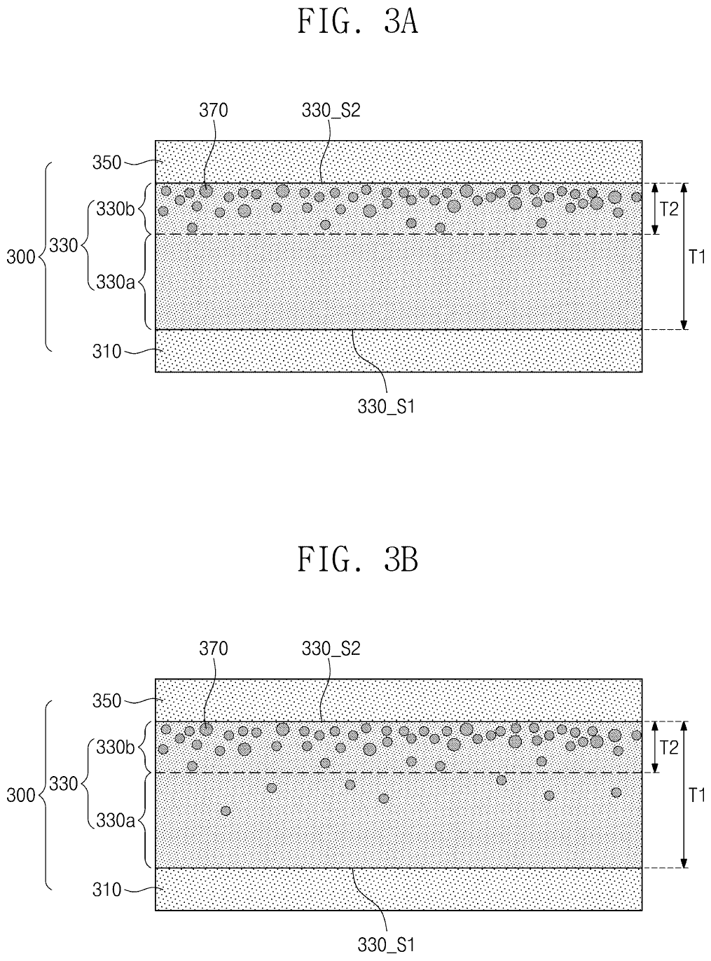

FIGS. 3A and 3B are sectional views, each illustrating a carrier adhesive member according to some example embodiments of inventive concepts.

Referring to FIG. 3A, a carrier adhesive member 300 may include a first release film 310, a second release film 350, and an adhesive layer 330. The first release film 310 and the second release film 350 may be spaced apart from each other, and the adhesive layer 330 may be disposed between the first release film 310 and the second release film 350. The first release film 310 may cover or at least partially cover a first surface 330_S1 of the adhesive layer 330. The second release film 350 may cover or at least partially cover a second surface 330_S2 of the adhesive layer 330, which is opposite to the first surface 330_S1.

The first and second release films 310 and 350 may be used to protect the first and second surfaces 330_S1 and 330_S2, respectively, of the adhesive layer 330. For example, each of the first and second release films 310 and 350 may include, for example, polyethylene terephthalate (PET), but example embodiments are not limited thereto.

The adhesive layer 330 may include a first region 330a and a second region 330b. The first region 330a may be in contact (for example, direct contact) with the first release film 310. The second region 330b may be placed on the first region 330a. The second region 330b may be in contact (for example, direct contact) with the second release film 350. In some example embodiments, the adhesive layer 330 may have a first thickness T1 ranging from, for example, 100 nm to 200 μm, but example embodiments are not limited thereto. The second region 330b of the adhesive layer 330 may have a second thickness T2 that is 0.01-0.5 times the first thickness T1, but example embodiments are not limited thereto. The second thickness T2 of the second region 330b may be smaller than or equal to a thickness of the first region 330a.

The second region 330b of the adhesive layer 330 may include, for example, metal particles 370. The first region 330a of the adhesive layer 330 may not include or substantially include the metal particles 370. A density of the metal particles 370 in the second region 330b may increase as a distance, for example a vertical distance, from the first region 330a increases. In other words, the density of the metal particles 370 may increase as a distance to the second surface 330_S2 of the second region 330b decreases (for example, when moving vertically towards the second surface 330_S2 from the first region 330A)

Some of the metal particles 370 may be disposed as close as possible, or substantially so, to the second surface 330_S2. In the present specification, the second region 330b may be referred to as a metal particle region. The metal particles 370 may have a size (or diameter) ranging from 50 nm to 100 μm.

In some example embodiments, the adhesive layer 330 may be formed of or include, for example at least one of silicone, acrylate, imide, rubber, and epoxy, but example embodiments are not limited thereto. The metal particles 370 may include, for example, at least one transition metal or material including a transition metal. For example, the metal particles 370 may be formed of or include at least one of Cu, Ti, W, and Sn, but inventive concepts are not limited to this example.

In some example embodiments, the formation of the carrier adhesive member 300 may include the following steps. The metal particles 370 may be added into a mixture containing, for example, at least one of, for example, silicone, acrylate, imide, rubber, and epoxy, and may be mixed and filtered to produce adhesive mixture solution. Here, the metal particles 370 may be, for example, formed of or include at least one metallic material (e.g., Cu) exhibiting a magnetic property. Next, on, for example, a conveyor belt exhibiting a magnetic property, the second release film 350 may be coated with the adhesive mixture solution and may be dried to form an adhesive mixture solution layer. Here, due to the magnetic property of the conveyor belt, the metal particles 370 in the adhesive mixture solution layer may be moved toward the conveyor belt (i.e., toward the second release film 350). The adhesive mixture solution layer on the second release film 350 may be cured to form the adhesive layer 330, and then, the first release film 310 may be attached to the adhesive layer 330. As a result of or according to the afore-described process, the metal particles 370 may be placed in a region that is adjacent to the second surface 330_S2, and the density of the metal particles 370 in the adhesive layer 330 may increase as a distance to the second surface 330_S2 decreases (for example, when moving away from the second surface 330_S2, as shown in FIG. 3A. Thereafter, a sawing process, for example, may be performed to form the carrier adhesive members 300, which are separated from each other.

Referring to FIG. 3B, in the carrier adhesive member 300 in some example embodiments, the first region 330a of the adhesive layer 330 may include the metal particles 370. The density of the metal particles 370 may be, for example, lower in the first region 330a than in the second region 330b, but example embodiments are not limited thereto. Except for the above features, the semiconductor package in the present embodiment may be substantially the same as or similar to those described with reference to FIG. 3A.

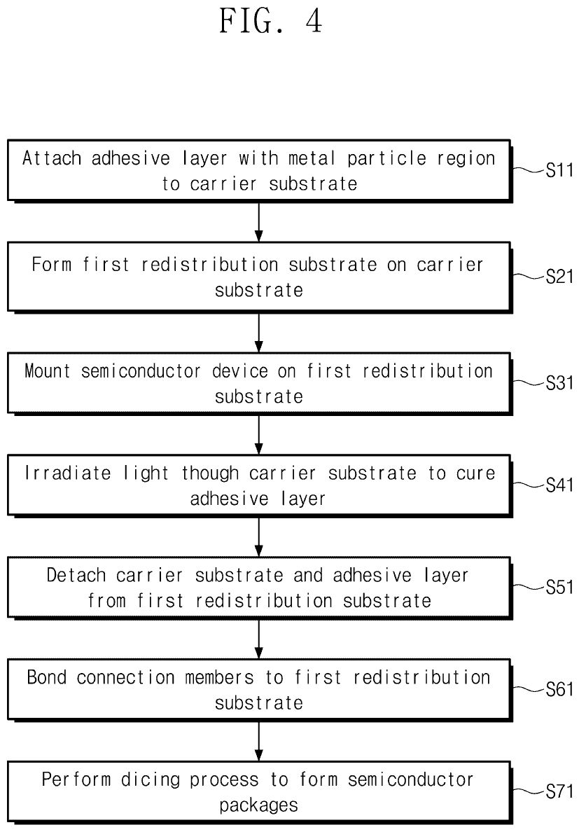

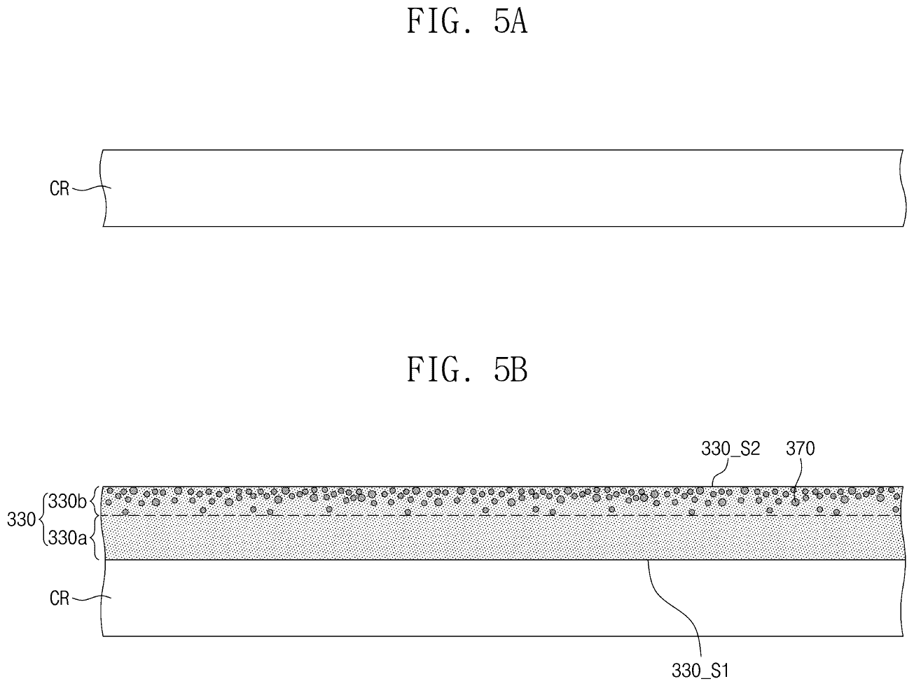

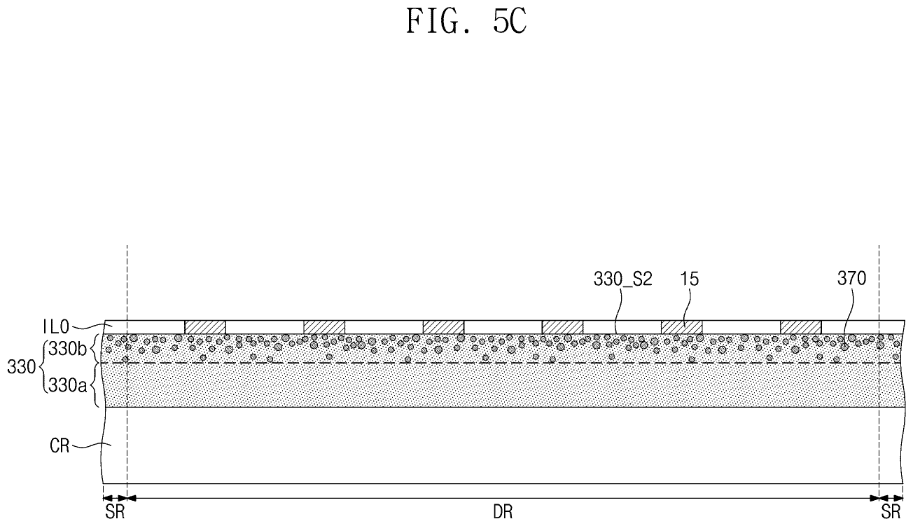

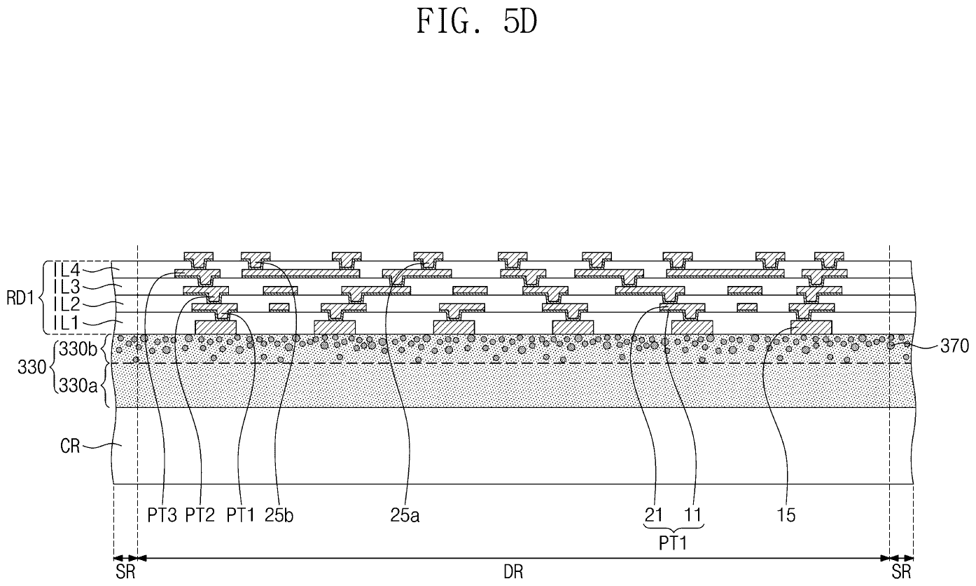

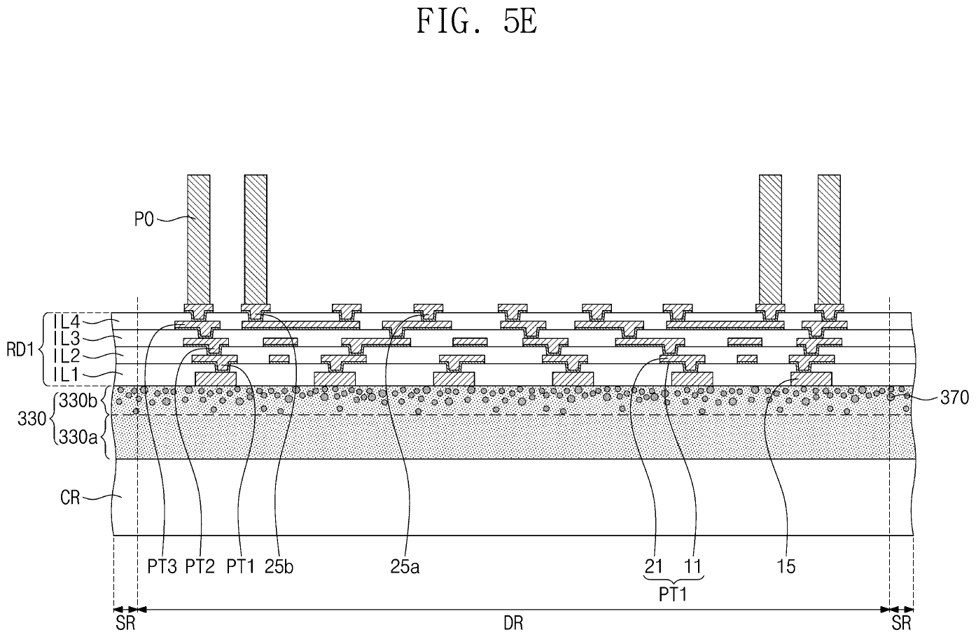

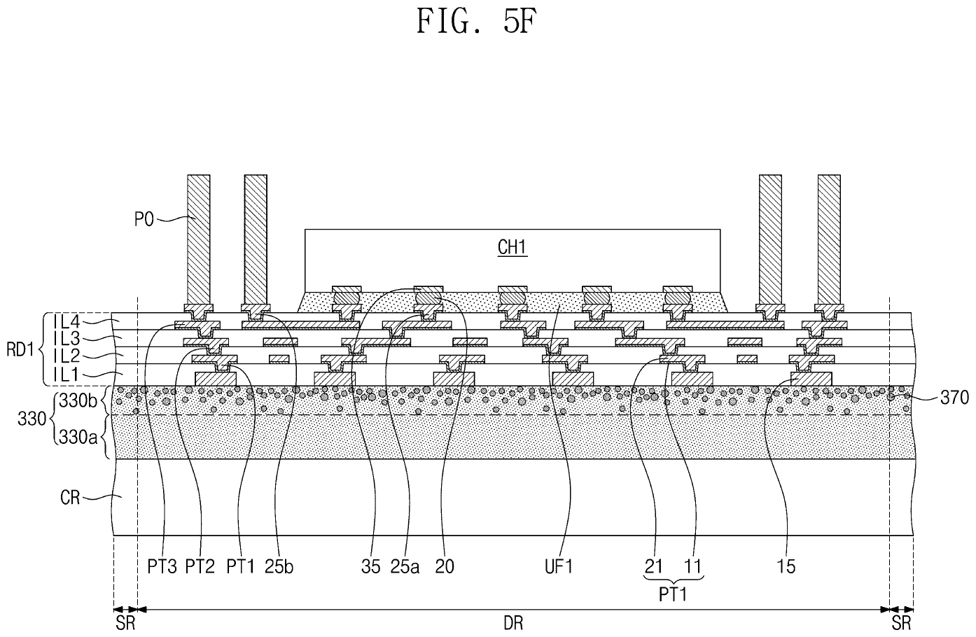

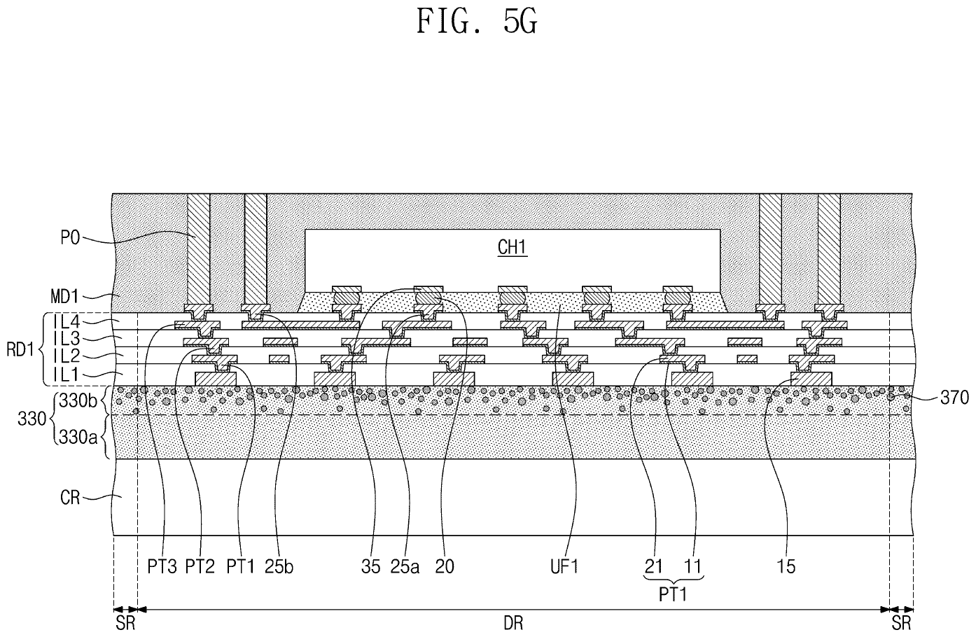

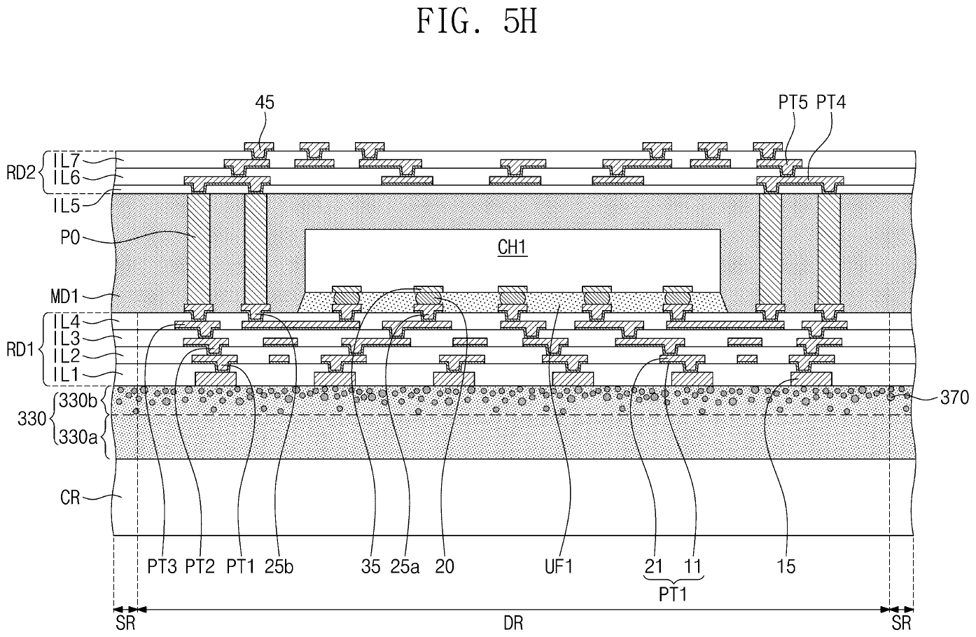

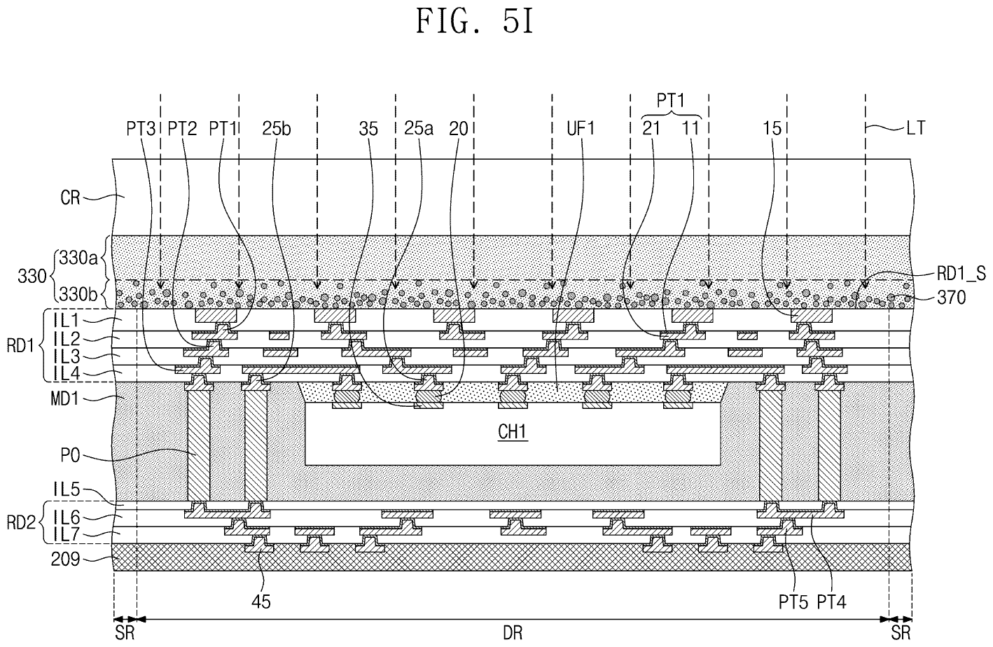

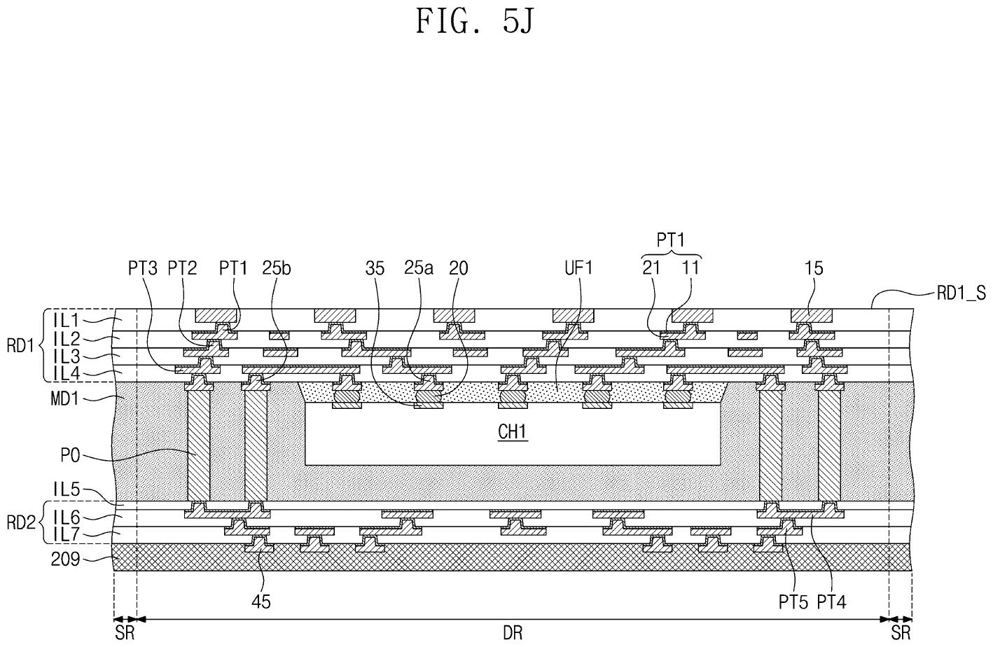

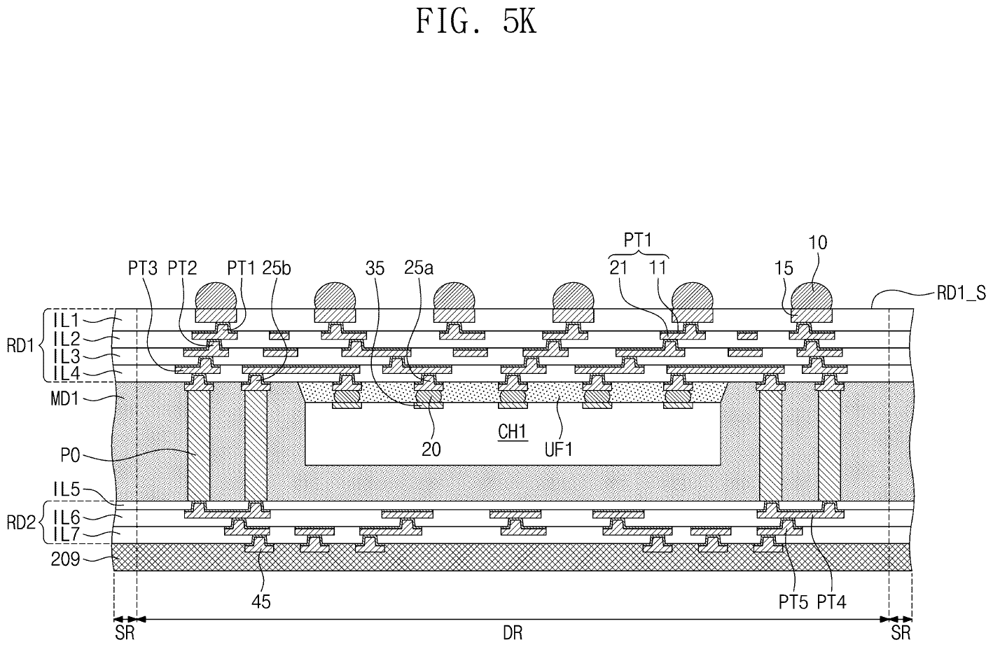

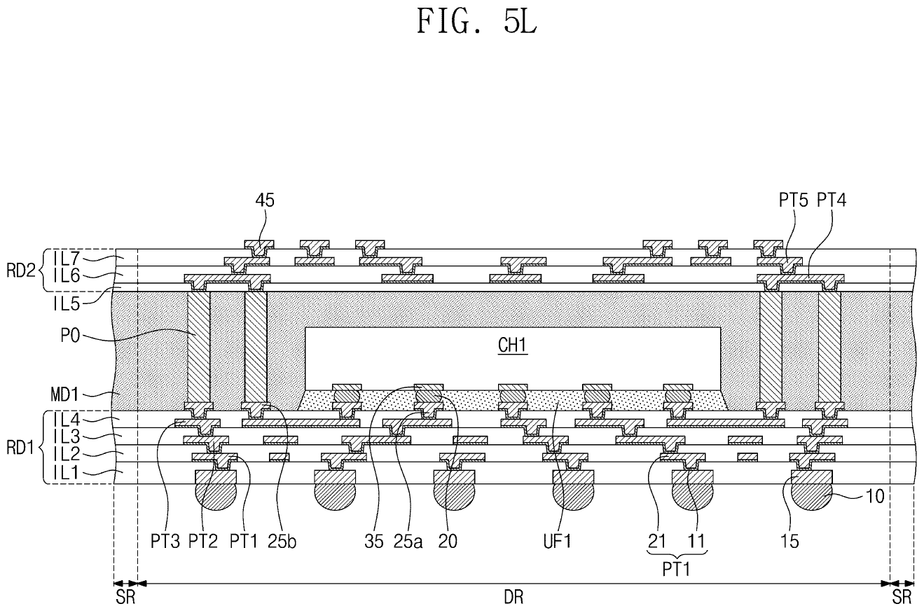

FIG. 4 is a flow chart illustrating methods of fabricating a semiconductor package according to some example embodiments of inventive concepts. FIGS. 5A to 5K are sectional views sequentially illustrating a method of fabricating a semiconductor package, according to some example embodiments of inventive concepts.

Referring to FIGS. 3A, 4, 5A, and 5B, a carrier substrate CR may be prepared. In some example embodiments, the carrier substrate CR may be formed of or include, for example, glass. The adhesive layer 330 with a metal particle region (e.g., the second region 330b) may be attached to the carrier substrate CR (in first step S11). Before the attaching of the adhesive layer 330 to the carrier substrate CR, the first and second release films 310 and 350 may be detached from the carrier adhesive member 300 to expose (for example, at least partially expose) the adhesive layer 330. Next, the adhesive layer 330 may be attached to the carrier substrate CR such that the first surface 330_S1 of the adhesive layer 330 is in contact with the carrier substrate CR.

Referring to FIGS. 4 and 5C, the carrier substrate CR and the adhesive layer 330 may include (for example, at least partially define) a plurality of separation regions SR and a device region DR between the separation regions. A separation region SR may be, for example, a scribe lane region, but example embodiments are not limited thereto.

A sub-redistribution layer IL0 may be formed on the adhesive layer 330. In some example embodiments, the sub-redistribution layer IL0 may be or include, for example, a photoimageable dielectric (PID) layer, but example embodiments are not limited thereto. The sub-redistribution layer IL0 may be formed through, for example, coating and baking processes. Thereafter, for example, exposure and developing processes may be performed to form openings, which expose (for example, at least partially expose) the adhesive layer 330, in the sub-redistribution layer IL0 and on the device region DR. Next, a plating process may be performed to form the under-bump patterns 15 filling the opening and covering (for example, at least partially covering) the second surface 330_S2 of the adhesive layer 330.

In a method of fabricating a semiconductor package according to some example embodiments of inventive concepts, in the plating process, the metal particles 370 of the adhesive layer 330 may be used as a seed layer. The density of the metal particles 370 in the second region 330b of the adhesive layer 330 may increase as a distance to the second surface 330_S2 decreases (for example, when moving upwards towards the second surface 330_S2) and the metal particles 370 may be placed adjacent to the second surface 330_S2. Since the metal particles 370, which may be adjacent to the second surface 330_S2, may be used as seed particles or seed metals, the under-bump patterns 15 may be formed on the adhesive layer 330 through the plating process.

Referring to FIGS. 4 and 5D, the first redistribution substrate RD1 may be formed on the carrier substrate CR (in second step S21). The first redistribution substrate RD1 may also include or at least partially define separation regions SR and the device region(s) DR therebetween.

The first redistribution layer IL1 may be formed on the carrier substrate CR. The first redistribution layer IL1 may be formed through, for example, the coating and baking processes. The first redistribution layer IL1 may be, for example, fused with the sub-redistribution layer IL0, but example embodiments are not limited thereto. The first redistribution layer IL1 may be, for example, patterned to form via holes, but example embodiments are not limited thereto. A conductive layer may be formed on the first redistribution layer IL1 to fill (for example, at least partially fill) the via holes and then may be patterned to form the first redistribution patterns PT1. These steps may be repeated as to form the first redistribution substrate RD1 including, for example, the first to fourth redistribution layers IL1 to IL4, the first to third redistribution patterns PT1 to PT3, and the first and second conductive patterns 25a and 25b.

Referring to FIGS. 4 and 5E, the conductive pillars P0 may be formed on the first redistribution substrate RD1 that is adjacent to an edge of the device region DR. The conductive pillars P0 may be in contact (for example, direct contact) with the second conductive patterns 25b, respectively.

Referring to FIGS. 4 and 5F, the first semiconductor device CH1, which includes the third conductive patterns 35 provided on a bottom surface thereof, may be prepared. The first semiconductor device CH1 may be bonded to the first redistribution substrate RD1 by, for example, a flip-chip bonding method using the second connection members 20 (in third step S31). The first semiconductor device CH1 may be disposed to be spaced apart from the conductive pillars P0. The first semiconductor device CH1 may be formed to have a height that is lower than one or more of the conductive pillars P0, or substantially so. The first under fill UF1 may be formed, for example, between the first semiconductor device CH1 and the first redistribution substrate RD1.

Referring to FIGS. 4 and 5G, a molding process may be performed to form the first molding member MD1 covering or at least partially covering the top surface of the first redistribution substrate RD1, the first semiconductor device CH1, and the conductive pillars P0. Thereafter, a CMP or etch-back process, for example, may be performed to remove at least a portion of the first molding member MD1 and at least a portion of the conductive pillars P0. Accordingly, the top surfaces of the conductive pillars P0 and the first molding member MD1 may be exposed (for example, at least partially exposed) to the outside. In such a case, the top surface of the first molding member MD1 may be coplanar or substantially coplanar with the top surfaces of the conductive pillars P0, but example embodiments are not limited thereto.

Referring to FIGS. 4 and 5H, the second redistribution substrate RD2 may be formed on the first semiconductor device CH1 and the first molding member MD1. The fifth to seventh redistribution layers IL5 to IL7, the fourth and fifth redistribution patterns PT4 and PT5, and the fourth conductive patterns 45 may be formed by the method described with reference to FIG. 5D. In such a case, the fourth redistribution patterns PT4 may be in contact with the conductive pillars P0, but example embodiments are not limited thereto.

Referring to FIGS. 4 and 5I, the semiconductor package of FIG. 5H may be attached to a wafer protection tape 209 in such a way that a top surface of the seventh redistribution layer IL7 of the second redistribution substrate RD2 is in contact (for example, direct contact) with the wafer protection tape 209. Next, light LT may be irradiated onto the carrier substrate CR to cure the adhesive layer 330 (in fourth step S41). In some example embodiments, the light LT may be, for example, ultraviolet (UV) light, but example embodiments are not limited thereto. The irradiation of the UV light may, for example, lead to a reduction of a bonding force between polymer chains in the adhesive layer 330 and accordingly a reduction of an adhesion strength of the adhesive layer 330, and in such a case, the adhesive layer 330 may be easily or relatively easily detached from a bottom surface RD1_S of the first redistribution substrate RD1.

However, inventive concepts are not limited thereto; for example, the carrier substrate CR and the adhesive layer 330 may be removed from the first redistribution substrate RD1 through various methods. Depending on material(s) of the adhesive layer 330, one of, for example, a thermal annealing method, a laser-assist peel-off method, and/or a mechanical lift-off method may be used to remove the carrier substrate CR and the adhesive layer 330.

Referring to FIGS. 4 and 5J, the carrier substrate CR and the cured adhesive layer 330 may be detached from the bottom surface RD1_S of the first redistribution substrate RD1 (e.g., from the bottom surface IL1_S of the first redistribution layer IL1 of FIG. 2) (in fifth step S51). Accordingly, the bottom surface RD1_S of the first redistribution substrate RD1 may be exposed to the outside. In such a case, since, as descried above, the adhesion strength between the adhesive layer 330 and the first redistribution substrate RD1 is reduced, the adhesive layer 330 and the carrier substrate CR may be easily or relatively easily detached from the first redistribution substrate RD1.

In a method of fabricating a semiconductor package according to some example embodiments of inventive concepts, since an additional seed layer is not formed on the adhesive layer 330, it may be possible to omit a process of etching the bottom surface RD1_S of the first redistribution substrate RD1, which is exposed (for example, at least partially exposed) after the detaching of the carrier substrate CR and the adhesive layer 330 from the first redistribution substrate RD1. Furthermore, since the metal particles 370 of the adhesive layer 330 are used as a seed layer, a seed particle or a seed metal may be absent on the bottom surface RD1_S of the first redistribution substrate RD1.

In a case where the bottom surface RD1_S of the first redistribution substrate RD1 is etched through a plasma and chemical etching process, a void or delamination issue may occur between the wafer protection tape 209 and the second redistribution substrate RD2, due to acidic or basic materials used. However, in the fabrication method according to some example embodiments of inventive concepts, since the bottom surface RD1_S of the first redistribution substrate RD1 is not etched, it may be possible to reduce or prevent the void and delamination issue, which is caused by the chemical etching process, from occurring between the wafer protection tape 209 and the second redistribution substrate RD2. Accordingly, the durability of the semiconductor package may be improved. Furthermore, a separation process may be performed at an increased speed, and thus, the productivity of the semiconductor package may be increased.

Referring to FIGS. 4 and 5K, the first connection members 10 may be bonded to the under-bump patterns 15 (in sixth step S61).

Referring to FIGS. 4 and 5L, the wafer protection tape 209 may be removed from the second redistribution substrate RD2. Next, for example, a dicing process using, for example, a laser beam may be performed to remove the first and second redistribution substrates RD1 and RD2 and the first molding member MD1 from the separation regions SR, and as a result, the semiconductor package 100 may be formed to have the structure of FIG. 1 (in seventh step S71).

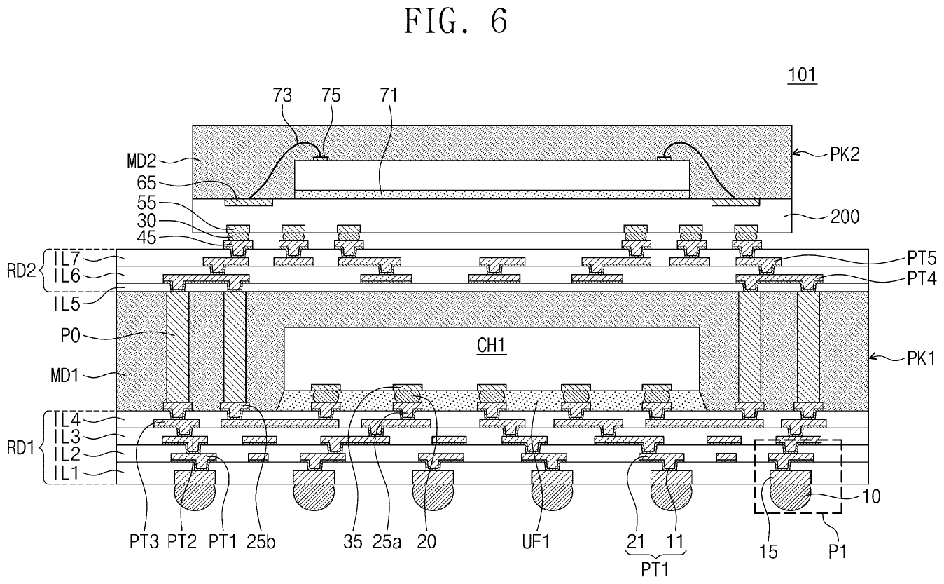

FIG. 6 is a sectional view illustrating a semiconductor package according to some example embodiments of inventive concepts.

Referring to FIGS. 2 and 6, a semiconductor package 101 may include a first sub-semiconductor package PK1, which has the same, substantially the same, or similar structure as the semiconductor package 100 of FIG. 1, and a second sub-semiconductor package PK2, which is mounted on the first sub-semiconductor package PK1. The second sub-semiconductor package PK2 may include a package substrate 200, a second semiconductor device CH2, which is mounted on the package substrate 200 using a bonding wire 73, and a second molding member MD2 covering them. The second molding member MD2 may be formed of or include the same material as the first molding member MD1. The portion ‘P1’ may have the same, substantially the same, or similar structure as that shown in the enlarged sectional view of FIG. 2.

In some example embodiments, the package substrate 200 may be, for example, a double-sided or multi-layered printed circuit board, but example embodiments are not limited thereto. The package substrate 200 may include fifth conductive patterns 55 and sixth conductive patterns 65, which are provided on bottom and top surfaces thereof. Internal lines (not shown) may be disposed in the package substrate 200 to connect the fifth conductive patterns 55 to the sixth conductive patterns 65.

The second sub-semiconductor package PK2 may be mounted on the second redistribution substrate RD2 by third connection members 30. The third connection members 30 may electrically connect the fifth conductive patterns 55 of the package substrate 200 to the fourth conductive patterns 45 of the second redistribution substrate RD2. The third connection members 30 may include at least one of solder balls, conductive bumps, and conductive pillars. The third connection members 30 may be formed of or include at least one of tin, lead, silver, copper, aluminum, gold, nickel, or any alloys thereof, but example embodiments are not limited thereto.

The bonding wire 73 may electrically connect the sixth conductive patterns 65 of the package substrate 200 to seventh conductive pads 75 of the second semiconductor device CH2. In some example embodiments, the bonding wire 73 may be formed of or include copper or gold. Each of the fifth to seventh conductive patterns 55, 65, and 75 may be formed of or include, for example, at least one of copper, aluminum, tungsten, nickel, gold, tin, titanium, or any alloys thereof, but example embodiments are not limited thereto. The chip adhesive member 71 may be interposed between the package substrate 200 and the second semiconductor device CH2.

However, inventive concepts are not limited to this structure of the second sub-semiconductor package PK2; for example, the second sub-semiconductor package PK2 may be provided in the form of or include a single semiconductor die, a single semiconductor chip, or a semiconductor package including a plurality of semiconductor chips. Except for the above features, the semiconductor package in the some example embodiments may be the same as substantially the same as or similar to those described with reference to FIGS. 1 to 5K.

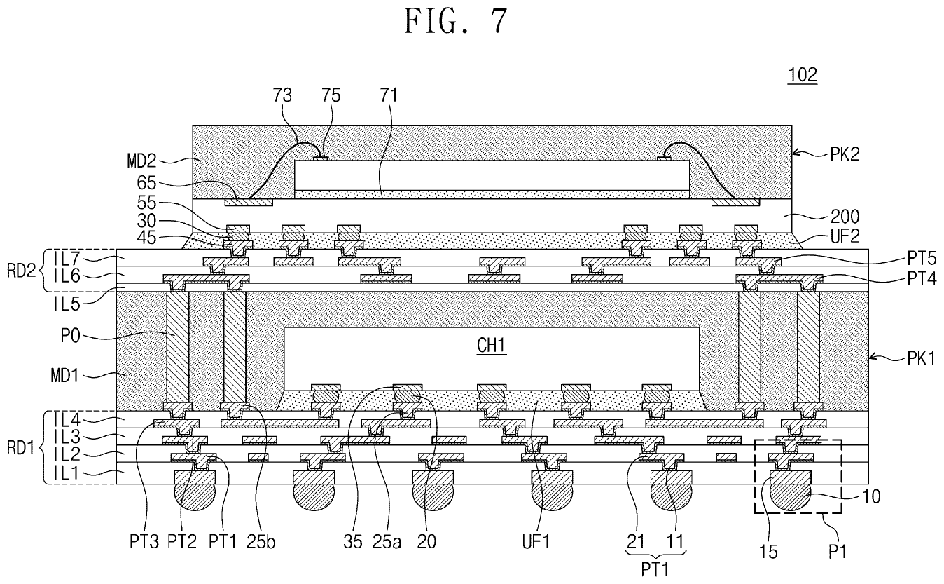

FIG. 7 is a sectional view illustrating a semiconductor package according to some example embodiments of inventive concepts.

Referring to FIGS. 2 and 7, a semiconductor package 102 may have the same, substantially the same, or substantially the same package structure as shown in FIG. 6 but may further include a second under fill UF2, which may be, for example, interposed between the second sub-semiconductor package PK2 and the second redistribution substrate RD2. The second under fill UF2 may be formed through, for example, dispensing and curing processes. The second under fill UF2 may include, for example, an epoxy resin and may protect the third connection members 30, but example embodiments are not limited thereto. The portion ‘P1’ may have the same, substantially the same the same, or similar structure as that shown in the enlarged sectional view of FIG. 2. Except for the above features, the semiconductor package in the present embodiment may be the same as, substantially the same as, or similar to those described with reference to FIGS. 1 to 6.

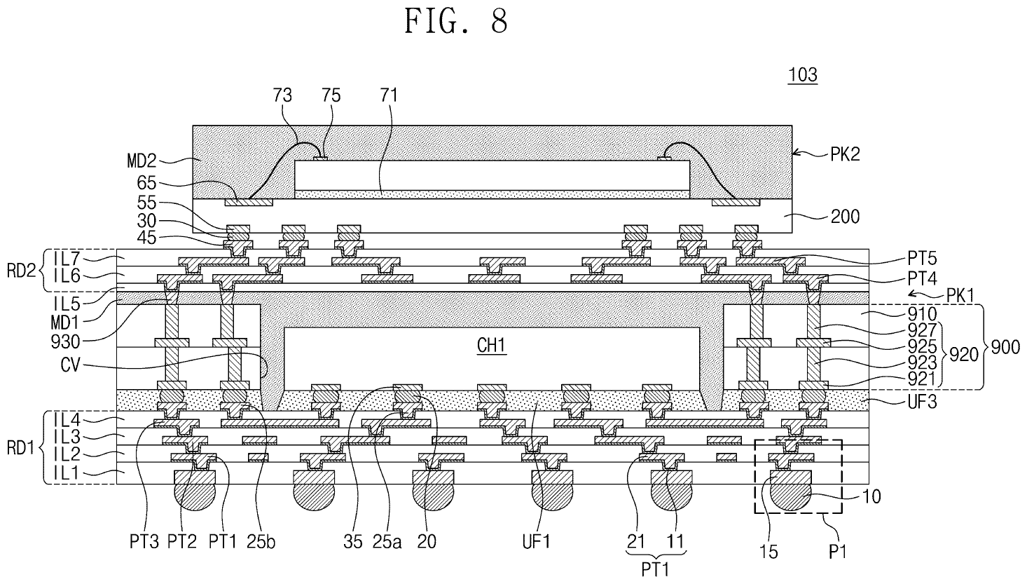

FIG. 8 is a sectional view illustrating a semiconductor package according to some example embodiments of inventive concepts.

Referring to FIGS. 2 and 8, in a semiconductor package 103 according to some example embodiments of inventive concepts, the first sub-semiconductor package PK1 may include the first redistribution substrate RD1, a connection substrate 900 and the first semiconductor device CH1, which are mounted on the first redistribution substrate RD1, the first molding member MD1, which is provided to cover (for example, at least partially cover) them, and the second redistribution substrate RD2, which is provided on the first molding member MD1. The second sub-semiconductor package PK2 may be configured to have the same, substantially the same, or similar features as the second sub-semiconductor package PK2 of FIG. 6. The portion ‘P1’ may have the same or similar structure as that shown in the enlarged sectional view of FIG. 2.

The first under fill UF1 may be interposed between the first semiconductor device CH1 and the first redistribution substrate RD1. The connection substrate 900 may, for example, include (for example, define or at least partially define) a cavity region CV, which may be provided in a center region thereof. The first semiconductor device CH1 may be disposed in the cavity region CV. The connection substrate 900 may include, for example, one or more of base layers 910 and a conductive structure 920. The base layers 910 may, for example, include an insulating material. For example, the base layers 910 may be formed of or include at least one of carbon-based materials, ceramics, or polymer, but example embodiments are not limited thereto. The conductive structure 920 may include a connection pad 921, a first connection via 923, a connection line 925, and a second connection via 927.

The connection substrate 900 may be connected to the first redistribution substrate RD1 by fourth connection members 40. A third under fill UF3 may be, for example, interposed between the connection substrate 900 and the first redistribution substrate RD1. A space defined or at least partially defined between an inner side surface of the cavity region CV of the connection substrate 900 and the first semiconductor device CH1 may be filled with the first molding member MD1. The third under fill UF3 may be formed of or include the same material as the first under fill UF1, but example embodiments are not limited thereto.

An auxiliary via 930 may be, for example, provided to penetrate the first molding member MD1 and to connect the second connection via 927 of the connection substrate 900 to the fourth redistribution patterns PT4 of the second redistribution substrate RD2. Unlike the illustrated structure, an under-filling material protecting the third connection members 30 may be further interposed between the first and second sub-semiconductor packages PK1 and PK2. Except for the above features, the semiconductor package in the present embodiment may be substantially the same as, substantially the same as, or similar to those described with reference to FIGS. 1 to 6.

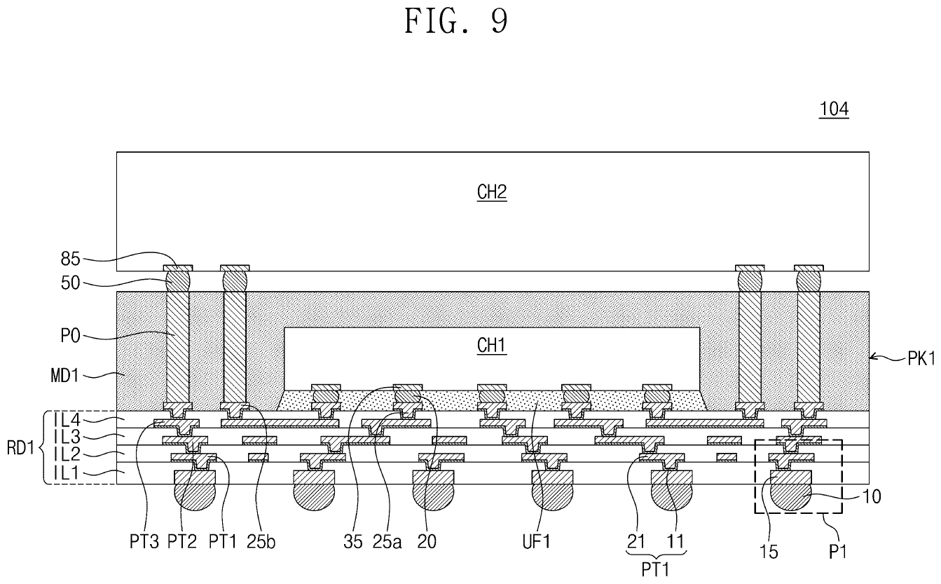

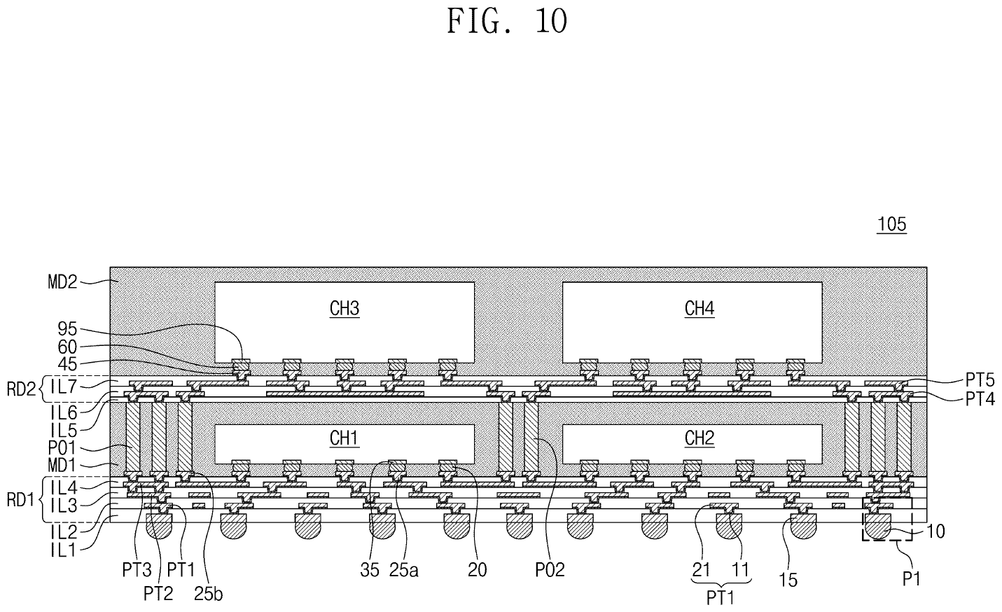

FIG. 9 is a sectional view illustrating a semiconductor package according to some example embodiments of inventive concepts.

Referring to FIGS. 2 and 9, a semiconductor package 104 may include a first sub-semiconductor package PK1, which has the same or similar structure as the semiconductor package 100 of FIG. 1, and a second semiconductor device CH2, which is mounted on the first sub-semiconductor package PK1. In some example embodiments, the second redistribution substrate RD2 may be omitted from the structure of FIG. 9. The portion ‘P1’ may have the same or similar structure as that shown in the enlarged sectional view of FIG. 2.

The second semiconductor device CH2 may be a memory chip (e.g., a DRAM chip). Eighth conductive patterns 85 may be disposed on a bottom surface of the second semiconductor device CH2. The eighth conductive patterns 85 may be in contact with the conductive pillars P0, respectively. The eighth conductive patterns 85 may be formed of or include at least one of copper, aluminum, tungsten, nickel, gold, tin, titanium, and any alloys thereof, but example embodiments are not limited thereto.

The second semiconductor device CH2 may be mounted on the first sub-semiconductor package PK1 by fifth connection members 50. The fifth connection members 50 may electrically connect the conductive pillars P0 of the first sub-semiconductor package PK1 to the eighth conductive patterns 85 of the second semiconductor device CH2. The fifth connection members 50 may include at least one of solder balls, conductive bumps, or conductive pillars. The fifth connection members 50 may be formed of or include, for example, at least one of tin, lead, silver, copper, aluminum, gold, nickel, and any alloys thereof, but example embodiments are not limited thereto. Except for the above features, the semiconductor package in the present embodiment may be substantially the same as, substantially the same as, or similar to those described with reference to FIGS. 1 to 5K.

FIG. 10 is a sectional view illustrating a semiconductor package according to some example embodiments of inventive concepts.

Referring to FIGS. 2 and 10, a semiconductor package 105 may include the structure of FIG. 1, which includes the first redistribution substrate RD1, and a plurality of semiconductor devices, which are mounted on the first redistribution substrate RD1. A first semiconductor device CH1 and a second semiconductor device CH2 may be disposed side-by-side on the first redistribution substrate RD1. Each of the first and second semiconductor devices CH1 and CH2 may be or include, for example, a memory chip (e.g., a DRAM chip), but example embodiments are not limited thereto.

First conductive pillars PO1, which are spaced apart from each other, may be disposed to enclose (for example, surround or at least partially surround) the first and second semiconductor devices CH1 and CH2. Second conductive pillars PO2 may be disposed between the first semiconductor device CH1 and the second semiconductor device CH2 to be spaced apart from each other. Each of the first and second conductive pillars PO1 and PO2 may be provided to penetrate (for example, extend or at least partially extend through) the first molding member MD1 and to electrically connect the first redistribution substrate RD1 to the second redistribution substrate RD2. The portion ‘P1’ may have the same, substantially the same, or similar structure as that shown in the enlarged sectional view of FIG. 2.

Third and fourth semiconductor devices CH3 and CH4 may be disposed side-by-side on the second redistribution substrate RD2. Each of the third and fourth semiconductor devices CH3 and CH4 may be a memory chip (e.g., a DRAM chip). Each of the third and fourth semiconductor devices CH3 and CH4 may include ninth conductive pads 95 that are disposed under a bottom surface thereof. Each of the third and fourth semiconductor devices CH3 and CH4 may be mounted on the second redistribution substrate RD2 by sixth connection members 60. The sixth connection members 60 may electrically connect the fourth conductive patterns 45 of the second redistribution substrate RD2 to the ninth conductive pads 95 of each of the third and fourth semiconductor devices CH3 and CH4. The sixth connection members 60 may include at least one of solder balls, conductive bumps, or conductive pillars. The sixth connection members 60 may be formed of or include at least one of tin, lead, silver, copper, aluminum, gold, nickel, and any alloys thereof, but example embodiments are not limited thereto.

Unlike the illustrated structure, an under filling element may be further interposed between the first redistribution substrate RD1 and the first and second semiconductor devices CH1 and CH2 or between the second redistribution substrate RD2 and the third and fourth semiconductor devices CH3 and CH4. Except for the above features, the semiconductor package in the present embodiment may be the same, substantially the same as or similar to those described with reference to FIGS. 1 to 5K.

In a method of fabricating a semiconductor package according to some example embodiments of inventive concepts, an adhesive layer of a carrier adhesive member may, for example, include a metal particle region. Metal particles may be distributed close or relatively to a surface of the adhesive layer, and the density of the metal particles may increase as a distance, for example a vertical distance, to the surface decreases. The metal particles may serve or be configured to serve as a seed layer. Since a seed layer is not formed on the adhesive layer, when a carrier substrate and the adhesive layer are removed from a redistribution substrate, it may be possible to omit a process of etching a bottom surface of the exposed redistribution substrate. In addition, there is no seed particle or seed metal left on the bottom surface of the redistribution substrate. Thus, it may be possible to reduce or prevent a void or delamination issue, which may occur between a wafer protection tape and a semiconductor package by a chemical etching process. Accordingly, the durability of the semiconductor package may be improved. Furthermore, a separation process may be performed at an increased speed, and thus, the productivity of the semiconductor package may be increased.

While example embodiments of inventive concepts have been particularly shown and described, it will be understood by one of ordinary skill in the art that variations in form and detail may be made therein without departing from the spirit and scope of the attached claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A method of fabricating a semiconductor package, comprising:
attaching an adhesive layer to a carrier substrate,
wherein the adhesive layer comprises
a first region in contact with the carrier substrate; and
a second region on the first region,
wherein the second region comprises metal particles, and
a density of the metal particles in the second region increases as a distance from the first region increases.

2. The method of claim 1, further comprising:
forming a first redistribution substrate on the second region of the adhesive layer;
mounting a semiconductor device on the first redistribution substrate;
irradiating light through the carrier substrate to cure the adhesive layer; and
detaching the carrier substrate and the adhesive layer from the first redistribution substrate.

3. The method of claim 2, further comprising:
forming a second redistribution substrate before the irradiating of the light through the carrier substrate, the second redistribution substrate being on the first redistribution substrate and on the semiconductor device.

4. The method of claim 2, further comprising:
forming a first molding member before the curing of the adhesive layer, the first molding member at least partially covering the first redistribution substrate and the semiconductor device.

5. The method of claim 2, wherein the forming of the first redistribution substrate comprises:
forming first conductive patterns, the first conductive patterns in contact with the second region of the adhesive layer; and
forming redistribution layers, the redistribution layers at least partially covering the first conductive patterns,
wherein the first redistribution substrate comprises the redistribution layers and the first conductive patterns.

6. The method of claim 1, before the attaching of the adhesive layer to the carrier substrate, further comprising:
preparing adhesive mixture solution including the metal particles;
coating a first film on a conveyor belt, the conveyor belt exhibiting a magnetic property with respect to the adhesive mixture solution as to form an adhesive mixture solution layer; and
curing the adhesive mixture solution layer to form the adhesive layer,
wherein the metal particles exhibit a magnetic property, and
the metal particles in the adhesive mixture solution layer are adjacent to the first film.

7. The method of claim 1, wherein a thickness of the adhesive layer ranges from 100 nm to 200 μm.

8. The method of claim 1, wherein the metal particles comprise at least one of Cu, Ti, W, or Sn.

9. The method of claim 1, wherein a size or diameter of the metal particles ranges from 50 nm to 100 μm.

10. The method of claim 1, wherein a thickness of the second region of the adhesive layer is 0.01 times to 0.5 times a thickness of the adhesive layer.

11. A method of fabricating a semiconductor package, comprising:
attaching an adhesive layer to a carrier substrate;
forming a first redistribution substrate on the adhesive layer;
mounting a semiconductor device on the first redistribution substrate;
irradiating light through the carrier substrate to cure the adhesive layer; and
detaching the carrier substrate and the adhesive layer from the first redistribution substrate,
wherein the adhesive layer comprises
a first region in contact with the carrier substrate; and
a second region on the first region and in contact with the first redistribution substrate,
wherein the second region comprises metal particles, and
a size or diameter of the metal particles ranges from 50 nm to 100 μm.

12. The method of claim 11, wherein the forming of the first redistribution substrate comprises:
forming first conductive patterns, the first conductive patterns in contact with the second region of the adhesive layer; and
forming redistribution layers, the redistribution layers at least partially covering the first conductive patterns,
wherein the redistribution substrate comprises the redistribution layers and the first conductive patterns.

13. The method of claim 11, further comprising:
forming conductive pillars on the first redistribution substrate before the mounting of the semiconductor device on the first redistribution substrate, the conductive pillars spaced apart from each other,
wherein each of the conductive pillars is spaced apart from the semiconductor device.

14. The method of claim 13, before the irradiating of the light to the carrier substrate, further comprising:
forming a first molding member, the first molding member at least partially covering the first redistribution substrate, the semiconductor device, and the conductive pillars;
removing at least a portion of the first molding member and at least a portion of the conductive pillars to at least partially expose a top surface of the first molding member and top surfaces of the conductive pillars; and
forming a second redistribution substrate on the first molding member and on the conductive pillars.

15. The method of claim 11, wherein a thickness of the second region of the adhesive layer is 0.01 times to 0.5 times a thickness of the adhesive layer.

16. The method of claim 11, wherein a density of the metal particles in the second region increases as a distance from the first region increases.

17. A method of fabricating a semiconductor package, comprising:
attaching an adhesive layer to a carrier substrate;
forming a first redistribution substrate on the adhesive layer;
mounting a semiconductor device on the first redistribution substrate;
forming a second redistribution substrate on the first redistribution substrate and on the semiconductor device;
irradiating light through the carrier substrate to cure the adhesive layer; and
detaching the carrier substrate and the adhesive layer from the first redistribution substrate,
wherein the adhesive layer comprises
a first region in contact with the carrier substrate; and
a second region on the first region and in contact with the first redistribution substrate,
wherein the second region comprises metal particles, and
the metal particles are absent in the first region.

18. The method of claim 17, further comprising:
forming conductive pillars before the mounting of the semiconductor device on the first redistribution substrate, the conductive pillars being spaced apart from each other, on the first redistribution substrate,
wherein each of the conductive pillars is spaced apart from the semiconductor device.

19. The method of claim 17, further comprising, before the attaching of the adhesive layer to the carrier substrate:
forming an adhesive mixture solution containing the metal particles;
coating a first film on a conveyor belt, the conveyor belt exhibiting a magnetic property with the adhesive mixture solution as to form an adhesive mixture solution layer; and
curing the adhesive mixture solution layer to form the adhesive layer,
wherein the metal particles exhibit a magnetic property, and
in the adhesive mixture solution layer, the metal particles are adjacent to the first film.

20. The method of claim 17, wherein a thickness of the adhesive layer ranges from 100 nm to 200 μm, and
a size or diameter of the metal particles ranges from 50 nm to 100 μm.
